(19) United States
(12) Patent Application Publication
(10) Pub. No.: US 2025/0050542 A1
(43) Pub. Date: Feb. 13, 2025

(54) METHOD FOR CUTTING SILICON INGOT

(71) Applicant: SUMCO CORPORATION, Tokyo (JP)

(72) Inventor: Daisuke HASHIMOTO, Tokyo (JP)

(73) Assignee: SUMCO CORPORATION, Tokyo (JP)

(21) Appl. No.: 18/723,008

(22) PCT Filed: Nov. 15, 2022
(86) PCT No.: PCT/JP2022/042414

§ 371 Date: Jun. 21, 2024

(30) Foreign Application Priority Data
Dec. 24, 2021 (JP) 2021-210753

(51) Int. Cl. B28D 5/04; B28D 5/00

(52) U.S. Cl. CPC B28D 5/045; B28D 5/0076

(57) ABSTRACT

A method for cutting a silicon ingot includes cutting a silicon ingot by causing a fixed-abrasive-grain wire to run at a speed in which the maximum speed is 1,200 m/minute or higher while supplying a coolant in which the percentage of water is more than 99%.

### TECHNICAL FIELD

The present invention relates to a method for cutting a silicon ingot.

### BACKGROUND ART

A multi-wire saw is constituted by wires that are wound at a fixed pitch into a helical shape around a plurality of rollers and is used in a step of manufacturing silicon wafers by cutting a silicon ingot. While the mainstream of the type of existing wire saws has been a loose-abrasive-grain type that performs cutting while supplying slurry containing abrasive grains to wires, a fixed-abrasive-grain type, which is high in processing efficiency, has been employed in recent years.

The fixed-abrasive-grain type uses fixed-abrasive-grain wires to which abrasive grains are fixed by electrodeposition or a resin, and performs cutting while supplying a coolant to the fixed-abrasive-grain wires. As the coolant, although a straight-type coolant, which is intended to be reused, has been used, a water-dilution-type coolant, which is a water-soluble coolant that is to be used by being diluted with water, has been widely used in recent years.

Since the thickness dimension of each silicon wafer is small, a space between fixed-abrasive-grain wires is also small such as less than 1 mm. Therefore, when a coolant is supplied to the fixed-abrasive-grain wires, a liquid film may be generated between the wires. Since the surface tension of water is strong, when a liquid film is generated by a coolant in which the amount of water is large as in a water-dilution-type coolant, the wires between which the liquid film is generated pull each other and decrease a wire space between the wires. A space between each of the wires whose wire space is decreased and a wire disposed adjacent thereto is increased, and thus, no liquid film is generated in the space. As a result, in a plurality of wires of a multi-wire saw disposed parallel to each other, a portion where a liquid film is generated and a space between wires is decreased and a portion where no liquid film is generated and a space between wires is increased are alternately generated. Consequently, the variation of the wire spaces causes variation in the thickness dimensions of wafers cut by the wires.

As a method for preventing such variation in the thicknesses of wafers caused by surface tension, Patent Literature 1 suggests a method in which, without a coolant supplied at the start of cutting, wires are caused to run at a low speed, each of the wires is inserted into a cutting start position on a workpiece to form a cut at the cutting start position on the workpiece, supply of the coolant is then started while the speed of the wires is increased, and cutting of the workpiece is continued at a regular speed.

### CITATION LIST

### Patent Literature

Patent Literature 1: JP 2011-104746 A

### SUMMARY OF THE INVENTION

### Problems to be Solved by the Invention

In the method in Patent Literature 1, since the coolant is not supplied at the start of cutting, the quality of a cut start portion of each wafer is degraded. In addition, since the speed of the wires is changed during cutting, a step is generated on a surface of each wafer, leading to abnormality in the quality of the wafers.

An object of the invention is to provide a method for cutting a silicon ingot that is capable of reducing variation in thickness dimensions of wafers and is also capable of preventing quality degradation of the wafers.

### Means for Solving the Problems

An aspect of the invention is a method for cutting a silicon ingot, the method including cutting a silicon ingot by causing a fixed-abrasive-grain wire to run at a speed in which a maximum speed is 1,200 m/minute or higher while supplying a coolant in which a percentage of water is more than 99%.

In the method for cutting a silicon ingot according to the aspect of the invention, the maximum speed of the fixed-abrasive-grain wire is preferably 2,000 m/minute or lower.

In the method for cutting a silicon ingot according to the aspect of the invention, a position at which the coolant is supplied to the fixed-abrasive-grain wire is preferably a position at which a distance from the silicon ingot is 60 mm or more.

In the method for cutting a silicon ingot according to the aspect of the invention, the position at which the coolant is supplied to the fixed-abrasive-grain wire is preferably a position at which the distance from the silicon ingot is 120 mm or less.

The method for cutting a silicon ingot according to the aspect of the invention preferably includes a first running of causing the fixed-abrasive-grain wire to run in a first direction, and a second running of causing the fixed-abrasive-grain wire to run in a second direction opposite to the first direction, the first running and the second running being repeated, in which the first running includes a first acceleration running of increasing a running speed of the fixed-abrasive-grain wire in a stopped state to the maximum speed while causing the fixed-abrasive-grain wire to run in the first direction, a first regular running of maintaining the running speed of the fixed-abrasive-grain wire at the maximum speed while causing the fixed-abrasive-grain wire to run in the first direction, and a first deceleration running of decreasing the maximum speed to a running speed of the fixed-abrasive-grain wire in a stopped state while causing the fixed-abrasive-grain wire to run in the first direction, and in which the second running includes a second acceleration running of increasing a running speed of the fixed-abrasive-grain wire in a stopped state to the maximum speed while causing the fixed-abrasive-grain wire to run in the second direction, a second regular running of maintaining the running speed of the fixed-abrasive-grain wire at the maximum speed while causing the fixed-abrasive-grain wire to run in the second direction, and a second deceleration running of decreasing the maximum speed to a running speed of the fixed-abrasive-grain wire in a stopped state while causing the fixed-abrasive-grain wire to run in the second direction.

In the method for cutting a silicon ingot according to the aspect of the invention, duration of the first regular running is preferably longer than duration of the second regular running.

According to the aspect of the invention, it is possible to reduce variation in thickness dimensions of wafers and also possible to prevent quality degradation of the wafers.

### BRIEF DESCRIPTION OF DRAWINGS

FIG. 1 is a schematic view of a structure of a multi-wire saw used in the invention.

FIG. 2 is an enlarged view of a main roller and fixed-abrasive-grain wires of the multi-wire saw.

FIG. 3 is a graph illustrating a relationship between the running speed of fixed-abrasive-grain wires and elapsed time.

FIG. 4 is a graph illustrating a relationship between the maximum speed of fixed-abrasive-grain wires and the PV value in a cut start section of a workpiece with respect to the percentage of water in a coolant.

FIG. 5 is a graph illustrating a relationship between the maximum speed of fixed-abrasive-grain wires and the PV value in a cut start section of a workpiece with respect to the supplying position of a coolant.

### DESCRIPTION OF EMBODIMENT

Hereinafter one exemplary embodiment of the invention will be described on the basis of the drawings.

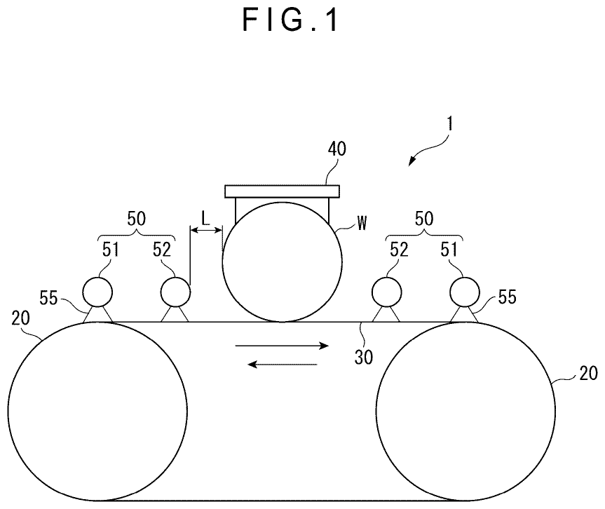

FIG. 1 is a schematic view of a multi-wire saw 1 used in an exemplary embodiment of the invention.

The multi-wire saw 1 is an apparatus that cuts a workpiece W that is a cylindrical silicon ingot into a plurality of silicon wafers, and the multi-wire saw 1 includes main rollers 20, fixed-abrasive-grain wires 30, a workpiece presser 40, and a coolant supplier 50. While not illustrated, there are provided a wire feeder that feeds the fixed-abrasive-grain wires 30 to the main rollers 20, and a wire receiver that receives the fixed-abrasive-grain wires 30. The wire feeder and the wire receiver are constituted by, for example, a feeder bobbin around which the fixed-abrasive-grain wires 30 are wound and a receiver bobbin, respectively.

Two to four main rollers 20 are provided. In the exemplary embodiment, two main rollers 20 are provided. Each of the feeder bobbin and the receiver bobbin is driven by a motor for bobbins, and at least one of the main rollers 20 is driven by a motor for rollers.

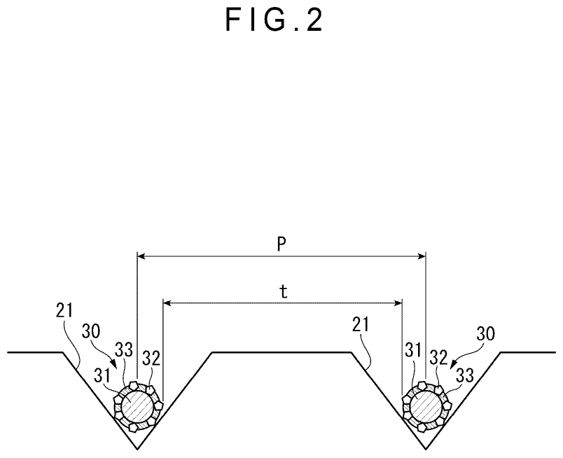

As illustrated in FIG. 2, a plurality of grooves 21 are formed at a fixed pitch on a surface of each main roller 20, and the fixed-abrasive-grain wires 30 are wound at these grooves 21. Consequently, a wire row in which a plurality of the fixed-abrasive-grain wires 30 are arranged at a fixed pitch in a longitudinal direction of the main rollers 20 is formed.

As a method for moving the fixed-abrasive-grain wires 30, there is a one-direction-feed cutting method in which the fixed-abrasive-grain wires 30 are moved at a fixed speed from the wire feeder toward the wire receiver to cut the workpiece W. The exemplary embodiment, however, employs a reciprocation cutting method in which the movement direction of the fixed-abrasive-grain wires 30 is reversed at a predetermined timing to cut the workpiece W.

When the motors are driven in a positive direction, the fixed-abrasive-grain wires 30 are fed from the feeder bobbin to run in a first direction (the right arrow direction in FIG. 1) and are wound around the receiver bobbin after circling around the main rollers 20. When the motors are driven in the opposite direction, the fixed-abrasive-grain wires 30 are fed from the receiver bobbin to run in a second direction (the left arrow direction in FIG. 1) opposite to the first direction and are wound around the feeder bobbin after circling around the main rollers 20. At this time, the feeding amount of the fixed-abrasive-grain wires 30 in a forward movement in which the motors are driven in the positive direction is set to be larger than the feeding amount of the fixed-abrasive-grain wires 30 in a backward movement in which the motors are driven in the opposite direction. Consequently, the fixed-abrasive-grain wires 30 run forward and backward repeatedly, and an unused portion of each of the fixed-abrasive-grain wires 30 is gradually fed while a used portion of each of the fixed-abrasive-grain wires 30 is gradually wound around the receiver bobbin.

As illustrated in FIG. 1, the workpiece presser 40 is provided above the workpiece W and moves downward in a state of holding the workpiece W to thereby press the workpiece W against the fixed-abrasive-grain wires 30 that run. Consequently, the workpiece W is sliced by the fixed-abrasive-grain wires 30 to manufacture a plurality of disk-shaped silicon wafers.

The coolant supplier 50 supplies a coolant 55 to the main rollers 20 and the fixed-abrasive-grain wires 30. The coolant supplier 50 includes an outside nozzle 51 and an inside nozzle 52. The coolant 55 is supplied through the outside nozzle 51 to the main rollers 20, and the coolant 55 is supplied through the inside nozzle 52 to the fixed-abrasive-grain wires 30.

The coolant 55 that is supplied from the coolant supplier 50 is a water-soluble coolant in which the percentage of water is more than 99%. As the coolant 55, a commercially available coolant diluted with water is used. For example, when one part of a commercially available coolant is diluted with 200 parts (vol %) of water, the water percentage obtained by dividing the volume of the water by the total volume is 200/201, which is approximately 99.5%, and a water-soluble coolant in which the percentage of water is more than 99% is obtained. The water percentage is actually higher than the above since the commercially available coolant contains 40% to 50% of water in addition to, for example, components such as propylene glycol and surfactant.

A distance from the inside nozzle 52 of the coolant supplier 50 to an end surface portion of the workpiece W close to the inside nozzle 52 in the first direction and the second direction, which are running directions of the fixed-abrasive-grain wires 30, is set to a distance L. Since the position of the inside nozzle 52 is a position at which the coolant 55 is supplied to the fixed-abrasive-grain wires 30, the position at which the coolant 55 is supplied to the fixed-abrasive-grain wires 30 is a position away from the workpiece W by the distance L. This distance L is set in a range from 60 mm to 120 mm.

FIG. 2 is a schematic sectional view of the fixed-abrasive-grain wires 30 wound at the grooves 21 of the main roller 20. The fixed-abrasive-grain wires 30 illustrated in FIG. 2 are each a fixed-abrasive-grain wire in which abrasive grains 32 are fixed by electrodeposition to a surface of a core wire 31 by using a Ni plating layer 33. Since the multi-wire saw 1 slices the workpiece W by using the cutting action of the abrasive grains 32 fixed to the surface of each fixed-abrasive-grain wire 30, the coolant 55 that does not contain abrasive grains can be used.

As the core wire 31 of each of the fixed-abrasive-grain wires 30, a steel wire (piano wire) or the like is usable. The diameter of the core wire 31 is preferably in a range from 80 μm to 130 μm. With the core wire 31 having a diameter of 80 μm or more, the fixed-abrasive-grain wire can have sufficient strength. With the core wire 31 having a diameter of 130 μm or less, a kerf loss in cutting can be reduced.

As the abrasive grains 32, known abrasive grains of diamond, cubic boron nitride (CBN), or the like are usable. The grain size of the abrasive grains 32 is preferably in a range from 5 μm to 16 μm. With the abrasive grains 32 having a grain size of 5 μm or more, it is possible to cause the abrasive grains 32 to efficiently contribute to cutting. With the abrasive grains 32 having a grain size of 16 μm or less, it is possible to reduce a kerf loss in cutting, inhibit damage caused on sections by the fixed-abrasive-grain wires 30, and improve flatness of the sections. Note that the abrasive grains 32 are not limited to be fixed to the core wire 31 by electrodeposition and may be fixed thereto with a resin.

In FIG. 2, the sign P indicates a space (pitch) between the grooves 21 of the main roller 20, and the sign t indicates a space between the fixed-abrasive-grain wires 30. The space P between the grooves 21 is set in accordance with a thickness dimension of a silicon wafer to be cut and is, for example, 960 μm. The space t between the fixed-abrasive-grain wires 30 is set in accordance with the space P and the outside diameter of the fixed-abrasive-grain wires 30. For example, when the outside diameter of the fixed-abrasive-grain wires 30 in which the abrasive grains 32 having an abrasive grain size of 6 to 12 μm are fixed by electrodeposition to the core wire 31 having a diameter of 120 μm is approximately 134 μm, the space t is approximately 826 μm. Further, when the outside diameter of the fixed-abrasive-grain wires 30 in which the abrasive grains 32 having an abrasive grain size of 8 to 16 μm are fixed by a resin to the core wire 31 having a diameter of 120 μm is approximately 145 μm, the space t is approximately 815 μm.

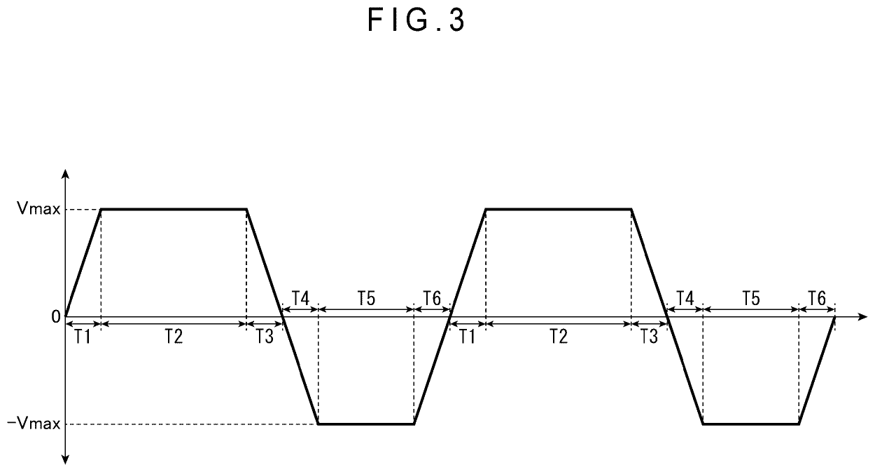

FIG. 3 is a graph illustrating a relationship between the running speed of the fixed-abrasive-grain wires 30 of the multi-wire saw 1 and elapsed time. For convenience, speeds in a first running step of causing the fixed-abrasive-grain wires 30 to run in the first direction are indicated by plus values and speeds in a second running step of causing the fixed-abrasive-grain wires 30 to run in the second direction are indicated by minus values. Note that the maximum speed in the second direction is the same as a maximum speed Vmax in the first direction. The maximum speed in the second direction is thus also represented by Vmax in the following description.

The first running step includes a first acceleration running step T1 of increasing a speed zero of the fixed-abrasive-grain wires 30 in a stopped state to the maximum speed Vmax while causing the fixed-abrasive-grain wires 30 to run in the first direction, a first regular running step T2 of maintaining the running speed of the fixed-abrasive-grain wires 30 at the maximum speed Vmax while causing the fixed-abrasive-grain wires 30 to run in the first direction, and a first deceleration running step T3 of decreasing the running speed Vmax to the speed zero of the fixed-abrasive-grain wires 30 in a stopped state while causing the fixed-abrasive-grain wires 30 to run in the first direction.

The second running step includes a second acceleration running step T4 of increasing the speed zero of the fixed-abrasive-grain wires 30 in a stopped state to the maximum speed Vmax while causing the fixed-abrasive-grain wires 30 to run in the second direction, a second regular running step T5 of maintaining the running speed of the fixed-abrasive-grain wires 30 at the maximum speed Vmax while causing the fixed-abrasive-grain wires 30 to run in the second direction, and a second deceleration running step T6 of decreasing the maximum speed Vmax to the speed zero of the fixed-abrasive-grain wires 30 in a stopped state while causing the fixed-abrasive-grain wires 30 to run in the second direction.

The first running step and the second running step are repeatedly performed, thereby performing the reciprocation cutting method in which the workpiece W is cut by reciprocation running of the fixed-abrasive-grain wires 30.

In FIG. 3, periods of time of the steps T1, T3, T4, and T6 at the time of acceleration or deceleration are the same and are each, for example, approximately 4 to 8 seconds. These periods of time are required to be increased as the maximum speed Vmax increases. The period of time of one cycle (T1 to T6) in which the fixed-abrasive-grain wires 30 are caused to reciprocate is, for example, approximately 60 to 200 seconds.

The duration of the first regular running step T2 is set to be longer than the duration of the second regular running step T5. For example, when one cycle is set to 60 seconds and the periods of time of acceleration and deceleration are each set to 5 seconds, the duration of the step T2 is 21 seconds and the duration of the step T5 is approximately 19 seconds. Consequently, the feeding amount of the fixed-abrasive-grain wires 30 during a forward movement is increased to be larger than the feeding amount thereof during a backward movement, and, with the fixed-abrasive-grain wires 30 running forward and backward repeatedly, an unused portion of each of the fixed-abrasive-grain wires 30 is gradually fed.

The maximum speed Vmax of the fixed-abrasive-grain wires 30 is preferably set in a range from 1,200 m/minute to 2,000 m/minute. Setting the maximum speed Vmax to 1,200 m/minute or higher increases wind pressure, thus inhibiting generation of liquid films between the fixed-abrasive-grain wires 30 by the coolant 55. Further, setting the maximum speed Vmax to 2,000 m/minute or lower reduces the heat generated by running of the wires to inhibit thermal deformation of the main rollers 20 and other members, and consequently inhibits warps of cut wafers.

### Method for Cutting Workpiece

Next, a method for cutting the workpiece W that is a silicon ingot will be described.

The main rollers 20 are driven to cause the fixed-abrasive-grain wires 30 to run forward and backward while the coolant 55 in which the percentage of water is more than 99% is supplied through the outside nozzle 51 and the inside nozzle 52 of the coolant supplier 50. At this time, in each of the first regular running step T2 and the second regular running step T5, the fixed-abrasive-grain wires 30 are caused to run while the maximum speed Vmax set in the range from 1,200 m/minute to 2,000 m/minute is maintained. Then, the workpiece W is cut by pressing the workpiece W against the fixed-abrasive-grain wires 30 by the workpiece presser 40 while supplying of the coolant 55 and the running speed of the fixed-abrasive-grain wires 30 are maintained. Consequently, the workpiece W is sliced to be processed into a large number of wafers.

### Actions and Effects in Exemplary Embodiment

When the coolant 55 in which the percentage of water is more than 99% is used, there is a likelihood that a liquid film is generated between the fixed-abrasive-grain wires 30 due to the surface tension of the water and causes variation in the pitch of the fixed-abrasive-grain wires 30. Thus, in particular, when the workpiece W having a cylindrical shape is cut, variation in the pitch of the fixed-abrasive-grain wires 30 is remarkable at the start of cutting at which a distance from each of the main rollers 20 to a processing point is the largest. Further, the fixed-abrasive-grain wires 30 are movable at the start of cutting of the workpiece W until the fixed-abrasive-grain wires 30 are inserted into the workpiece W, and spaces between the fixed-abrasive-grain wires 30 are thus easily decreased to allow formation of liquid films in the spaces.

For the above, in the method for cutting a silicon ingot in the exemplary embodiment, the maximum speed Vmax of the fixed-abrasive-grain wires 30 is set to 1,200 m/minute or higher. This inhibits generation of liquid films by wind pressure as well as variation in the pitch of the fixed-abrasive-grain wires 30, and thus variation in the thickness dimension in a cut start section of the workpiece W can be reduced.

Since cutting of the workpiece W is started while the coolant 55 is supplied to the fixed-abrasive-grain wires 30, quality degradation of a cut start portion of each wafer is preventable. Further, since the running speed of the fixed-abrasive-grain wires 30 is not changed during cutting of the workpiece W, it is possible to prevent generation of a step on a surface of each wafer.

Since the maximum speed Vmax of the fixed-abrasive-grain wires 30 is set to 2,000 m/minute or lower, it is possible to inhibit the heat generated by running of the wires. It is thus possible to inhibit thermal deformation of the main rollers 20 and the other members and possible to inhibit warps of cut wafers.

If a position at which the coolant 55 is supplied through the inside nozzle 52 to the fixed-abrasive-grain wires 30 is close to the workpiece W, a period of time for applying wind pressure to the coolant 55 supplied to the fixed-abrasive-grain wires 30 is short, and it may be not possible to prevent generation of liquid films. For the above, in the exemplary embodiment, the coolant 55 is supplied at a position at which the distance L from the workpiece W is 60 mm or more, and it is thus possible to secure the period of time of applying wind pressure and possible to inhibit generation of liquid films.

In addition, if the position at which the coolant 55 is supplied through the inside nozzle 52 to the fixed-abrasive-grain wires 30 is too far from the workpiece W, the coolant 55 does not reach a processing point, and a processing load due to wire clogging increases, leading to quality degradation. For the above, in the exemplary embodiment, the coolant 55 is supplied at a position at which the distance L from the workpiece W is 120 mm or less, and it is thus possible to supply the coolant 55 to the processing point.

### Modifications

While an exemplary embodiment of the invention has been described above in detail with reference to the drawings, specific components or configurations are not limited to those in this exemplary embodiment and may be included in the invention even when variously improved or changed in design and the like within a scope that does not deviate from the gist of the invention.

The multi-wire saw 1 may be of a three-shaft type including three main rollers or a type including four main rollers. The coolant 55 is not limited to a 200-time-dilution coolant that is obtained by diluting one part of a commercially available coolant with 200 parts (vol %) of water and may be any coolant as long as being a coolant in which the percentage of water is more than 99%.

It is sufficient for the maximum speed Vmax of the fixed-abrasive-grain wires 30 to be 1,200 m/minute or higher, and the upper limit value of the maximum speed Vmax may be a speed that is higher than 2,000 m/minute and may be, for example, 2, 100 m/minute. In addition, the maximum speed in the first direction and the maximum speed in the second direction, which are normally set to be the same, may be set to be speeds that are different from each other.

The supplying position of the coolant 55 may be a position at which the distance from the workpiece W is more than 120 mm, for example, 150 mm. The supplying position of the coolant 55 also may be a position at which the distance from the workpiece W is less than 60 mm, for example, 50 mm.

The method for cutting the workpiece W is not limited to the reciprocation cutting method, in which the fixed-abrasive-grain wires 30 are caused to reciprocate, and may be the one-direction-feed cutting method, in which the fixed-abrasive-grain wires 30 are caused to run in one direction. In this one-direction-feed cutting method, it is only necessary to cause the fixed-abrasive-grain wires 30 to run at the start of running by increasing the speed zero to the maximum speed Vmax, thereafter cause the fixed-abrasive-grain wires 30 to run in one direction while maintaining the maximum speed Vmax, and, after cutting, decrease the maximum speed Vmax to the speed zero. In other words, it is only necessary for the invention to include cutting the workpiece W by performing regular running in which the running speed of the fixed-abrasive-grain wires 30 is maintained at the maximum speed Vmax, while a coolant in which the percentage of water is more than 99% is supplied.

### EXAMPLE

Next, Example of the invention will be described. In Example, an ingot having a diameter of 300 mm was used. In addition, rollers having a pitch of 960 μm, wires in which the diameter of a core wire was 120 μm, and abrasive grains having a grain size of 6 to 12 μm were used. The outside diameter of the wires was 134 μm. Note that the invention is not limited to this Example.

### Evaluation on Water Percentage in Coolant

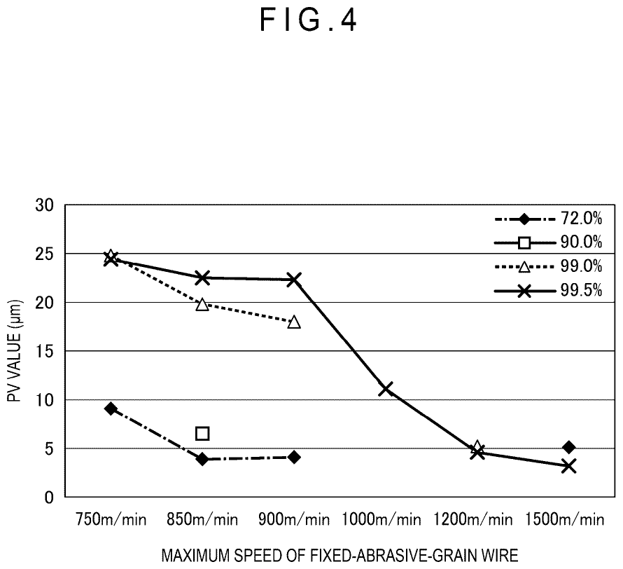

FIG. 4 is a graph illustrating a relationship between the maximum speed Vmax of the fixed-abrasive-grain wires 30 and the PV value in a 30-mm cut start section of the workpiece W with respect to the percentage of water in the coolant 55. The PV value (Peak to Valley) is a difference between the maximum value and the minimum value of the wafer thickness in a section having 30 mm from a cut start position of the workpiece W.

As illustrated in FIG. 4, when the percentage of water was low such as 72.0% or 90.0%, the PV value was small such as 10 μm or less even when the maximum speed Vmax of the wire running speed was low such as 900 m/minute or lower. That is, it was found that a wire-running-speed dependency of the PV value at a low water percentage was low. In contrast, it was found that, with the percentage of water being 99.0% or 99.5%, the PV value was also large such as 15 μm or more when the maximum speed Vmax was low such as 900 m/minute or lower. In particular, with the percentage of water being more than 99% such as 99.5%, it was found as follows: although the PV value was 10 μm or more even when the maximum speed Vmax was 1,000 m/minute, the PV value was reduced to 5 μm or less when the maximum speed Vmax was set to 1,200 m/minute or higher.

### Evaluation on Wire Running Speed

Table 1 shows results obtained through tests by evaluating the PV value, which indicates variation in the thickness of the workpiece W in the 30-mm cut start section, and the Warp, which indicates a warp of a wafer, with respect to the maximum speed Vmax of the fixed-abrasive-grain wires 30. In the tests, the coolant 55 in which the percentage of water was 99.5% was used. The Warp is a sum of the maximum value and the minimum value of a distance from a reference surface, which is specified in a wafer in a state of not being sucked and fixed, to a wafer center surface.

TABLE 1

| MAXIMUM SPEED Vmax (m/min) | PV VALUE (μm) | Warp (μm) |
|---|---|---|
| 2,200 | 6.1 | 55.2 |
| 2,000 | 5.8 | 14.4 |
| 1,800 | 6.1 | 13.7 |
| 1,500 | 3.2 | 12.7 |
| 1,200 | 4.6 | 12.2 |
| 1,000 | 11.1 | 11.8 |
| 900 | 22.3 | 13.1 |

From the results in Table 1, it was confirmed that, when the maximum speed Vmax was 1,200 m/minute or higher, generation of liquid films was inhibited by wind pressure, variation in the thickness of the wafer in the 30-mm cut start section was inhibited, and the PV value was small such as 5 μm or less. In addition, it was confirmed that, when the maximum speed Vmax was 2,000 m/minute or lower, generation of processing heat was inhibited, and the Warp had a small value such as 15 μm or less. Accordingly, it was confirmed that, when the coolant 55 in which the percentage of water is more than 99% is to be supplied, the maximum speed Vmax is preferably set in the range from 1,200 m/minute to 2,000 m/minute.

### Evaluation on Coolant Supplying Position

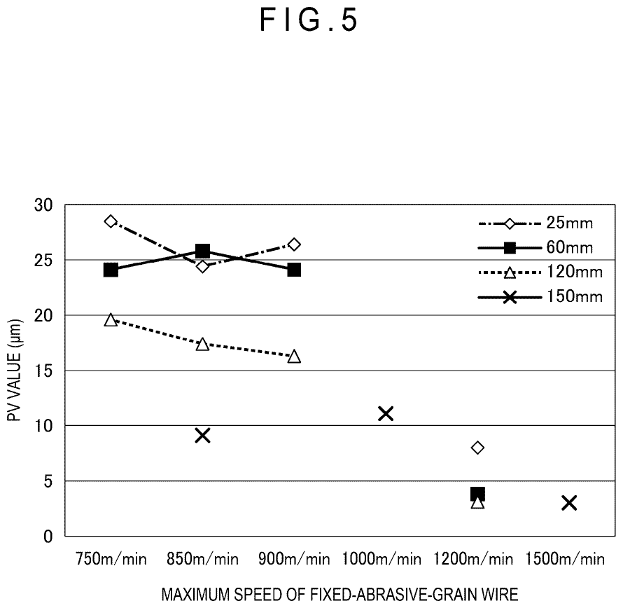

FIG. 5 is a graph illustrating a relationship between the maximum speed Vmax of the fixed-abrasive-grain wires 30 and the PV value in the 30-mm cut start section of the workpiece W with respect to the supplying position of the coolant 55.

Specifically, the graph shows results obtained by setting the coolant supplying position and the maximum speed Vmax, slicing one to three silicon ingots, selecting five wafers from five parts, including a top part, a part between the top part and a central part, the central part, a part between the central part and a bottom part, and the bottom part of each of the silicon ingots, and averaging the PV values in cut start sections of the wafers.

As illustrated in FIG. 5, with the maximum speed Vmax being 1,000 m/minute or lower, the PV value decreased when the distance L from the supplying position of the coolant 55 to an end surface portion of the workpiece W close to the inside nozzle 52 increased. Similarly, with the maximum speed Vmax being 1,200 m/minute or higher, the PV value also decreased when the distance L increased. In particular, when the distance L was 60 mm or more, the PV value was reduced to 5 μm or less.

With the maximum speed Vmax being 1,200 m/minute or higher, the PV value was almost the same as that when the distance L was 60 mm or 120 mm, even when the distance L was set to be large such as 150 mm.

Meanwhile, when the distance L increases, the coolant 55 does not reach a processing point and a processing load due to wire clogging increases, leading to quality degradation.

Therefore, it was confirmed that the distance L from an end surface portion of the workpiece W close to the inside nozzle 52 to the supplying position of a coolant is preferably in a range from 60 mm to 120 mm from the point of view of being able to decrease the PV value and inhibiting an increase in costs.

### EXPLANATION OF CODES

1 . . . multi-wire saw, 20 . . . main roller, 21 . . . groove, 30 . . . fixed-abrasive-grain wire, 31 . . . core wire, 32 . . . abrasive grain, 40 . . . workpiece presser, 50 . . . coolant supplier, 51 . . . outside nozzle, 52 . . . inside nozzle, 55 . . . coolant

1. A method for cutting a silicon ingot, the method comprising: cutting a silicon ingot by causing a fixed-abrasive-grain wire to run at a speed in which a maximum speed is 1,200 m/minute or higher while supplying a coolant in which a percentage of water is more than 99%.

2. The method for cutting a silicon ingot according to claim 1,
wherein the maximum speed of the fixed-abrasive-grain wire is 2,000 m/minute or lower.

3. The method for cutting a silicon ingot according to claim 1,
wherein a position at which the coolant is supplied to the fixed-abrasive-grain wire is a position at which a distance from the silicon ingot is 60 mm or more.

4. The method for cutting a silicon ingot according to claim 3,
wherein the position at which the coolant is supplied to the fixed-abrasive-grain wire is a position at which the distance from the silicon ingot is 120 mm or less.

5. The method for cutting a silicon ingot according to claim 1, the method comprising:
a first running of causing the fixed-abrasive-grain wire to run in a first direction; and
a second running of causing the fixed-abrasive-grain wire to run in a second direction opposite to the first direction, the first running and the second running being repeated,
wherein the first running includes
a first acceleration running of increasing a running speed of the fixed-abrasive-grain wire in a stopped state to the maximum speed while causing the fixed-abrasive-grain wire to run in the first direction,
a first regular running of maintaining the running speed of the fixed-abrasive-grain wire at the maximum speed while causing the fixed-abrasive-grain wire to run in the first direction, and
a first deceleration running of decreasing the maximum speed to a running speed of the fixed-abrasive-grain wire in a stopped state while causing the fixed-abrasive-grain wire to run in the first direction, and
wherein the second running includes
a second acceleration running of increasing a running speed of the fixed-abrasive-grain wire in a stopped state to the maximum speed while causing the fixed-abrasive-grain wire to run in the second direction,
a second regular running of maintaining the running speed of the fixed-abrasive-grain wire at the maximum speed while causing the fixed-abrasive-grain wire to run in the second direction, and
a second deceleration running of decreasing the maximum speed to a running speed of the fixed-abrasive-grain wire in a stopped state while causing the fixed-abrasive-grain wire to run in the second direction.

6. The method for cutting a silicon ingot according to claim 5,
wherein duration of the first regular running is longer than duration of the second regular running.

7. The method for cutting a silicon ingot according to claim 2, the method comprising:
a first running of causing the fixed-abrasive-grain wire to run in a first direction; and
a second running of causing the fixed-abrasive-grain wire to run in a second direction opposite to the first direction, the first running and the second running being repeated,
wherein the first running includes
a first acceleration running of increasing a running speed of the fixed-abrasive-grain wire in a stopped state to the maximum speed while causing the fixed-abrasive-grain wire to run in the first direction,
a first regular running of maintaining the running speed of the fixed-abrasive-grain wire at the maximum speed while causing the fixed-abrasive-grain wire to run in the first direction, and
a first deceleration running of decreasing the maximum speed to a running speed of the fixed-abrasive-grain wire in a stopped state while causing the fixed-abrasive-grain wire to run in the first direction, and
wherein the second running includes
a second acceleration running of increasing a running speed of the fixed-abrasive-grain wire in a stopped state to the maximum speed while causing the fixed-abrasive-grain wire to run in the second direction,
a second regular running of maintaining the running speed of the fixed-abrasive-grain wire at the maximum speed while causing the fixed-abrasive-grain wire to run in the second direction, and
a second deceleration running of decreasing the maximum speed to a running speed of the fixed-abrasive-grain wire in a stopped state while causing the fixed-abrasive-grain wire to run in the second direction.

8. The method for cutting a silicon ingot according to claim 7,
wherein duration of the first regular running is longer than duration of the second regular running.
